(19) United States
(12) Patent Application Publication
(10) Pub. No.: US 2017/0194345 A1
(43) Pub. Date: Jul. 6, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Kazuhiro NOJIMA, Yokkaichi (JP)

(73) Assignee: Kabushiki Kaisha Toshiba, Minato-ku (JP)

(21) Appl. No.: 15/198,135

(22) Filed: Jun. 30, 2016

Related U.S. Application Data
(60) Provisional application No. 62/273,173, filed on Dec. 30, 2015.

(51) Int. Cl. H01L 27/115; H01L 23/528

(52) U.S. Cl. CPC H01L 27/11582; H01L 27/11565; H01L 23/528

(57) ABSTRACT

According to one embodiment, a semiconductor memory device includes a substrate, a stacked body, a semiconductor pillar, a charge storage film, a plurality of interconnect portions, and at least one columnar member. Each of the plurality of interconnect portions spreads along the stacking direction and a first direction crossing the stacking direction. The plurality of interconnect portions are disposed along the first direction and a second direction crossing the stacking direction and the first direction. The at least one columnar member is provided in the stacked body and extends in the stacking direction. The plurality of interconnect portions include a first interconnect portion and a second interconnect portion adjacent to each other in the first direction. The columnar member is located between a first end portion of the first interconnect portion and a second end portion of the second interconnect portion.

### CROSS-REFERENCE TO RELATED APPLICATIONS

This application is based upon and claims the benefit of priority from U.S Provisional Patent Application 62/273,173, filed on Dec. 30, 2015; the entire contents of which are incorporated herein by reference.

### FIELD

Embodiments described herein relate generally to a semiconductor memory device and a method for manufacturing the same.

### BACKGROUND

A memory device having a three-dimensional structure has been proposed, in which memory holes are formed in a stacked body including a plurality of electrode films stacked with an insulating film therebetween, and a silicon body serving as a channel is provided on a side wall of the memory hole with a charge storage film between the side wall and the silicon body. The electrode film functions as a control gate in a memory cell and is formed by burying metal or the like in a cavity resulting from the removal of a portion of the stacked body. In such a three-dimensional memory device, when a portion of the stacked body is replaced with the metal or the like through a slit formed in the stacked body, it is feared that the stacked body may be bent and deformed due to the slit or the cavity.

### BRIEF DESCRIPTION OF THE DRAWINGS

FIG. 1 is a plan view showing a semiconductor memory device according to a first embodiment;

FIG. 2 is a sectional view showing the semiconductor memory device according to the first embodiment;

FIG. 3 is a sectional view showing a portion of the semiconductor memory device according to the first embodiment;

FIG. 4 is a sectional view showing a portion of the semiconductor memory device according to the first embodiment;

FIG. 5 is a sectional view showing a portion of the semiconductor memory device according to the first embodiment;

FIG. 6A and FIG. 6B are a plan view and a sectional view showing portions of another semiconductor memory device according to the first embodiment;

FIG. 7A and FIG. 7B to FIG. 10A and FIG. 10B are diagrams showing a method for manufacturing the semiconductor memory device according to the first embodiment;

FIG. 11A is a plan view showing a portion of a semiconductor memory device according to a second embodiment;

FIG. 11B and FIG. 11C are sectional views showing portions of the semiconductor memory device according to the second embodiment;

FIG. 12A and FIG. 12B to FIG. 14A and FIG. 14B are diagrams showing a method for manufacturing the semiconductor memory device according to the second embodiment;

FIG. 15 is a plan view showing a portion of a semiconductor memory device according to a third embodiment;

FIG. 16 is a plan view showing a portion of the semiconductor memory device according to the third embodiment; and

FIG. 17A and FIG. 17B are sectional views showing portions of the semiconductor memory device according to the third embodiment.

### DETAILED DESCRIPTION

According to one embodiment, a semiconductor memory device includes a substrate, a stacked body, a semiconductor pillar, a charge storage film, a plurality of interconnect portions, and at least one columnar member. Each of the plurality of interconnect portions spreads along the stacking direction and a first direction crossing the stacking direction. The plurality of interconnect portions are disposed along the first direction and a second direction crossing the stacking direction and the first direction. The at least one columnar member is provided in the stacked body and extends in the stacking direction. The plurality of interconnect portions include a first interconnect portion and a second interconnect portion adjacent to each other in the first direction. The columnar member is located between a first end portion of the first interconnect portion and a second end portion of the second interconnect portion.

Various embodiments will be described hereinafter with reference to the accompanying drawings. In the respective drawings, the same elements are labeled with like reference numerals. All of drawings shown in the following are schematic. For example, for convenience to see the drawings, in some drawings, some constituent features are omitted or the number of the constituent features is reduced for drawing. The number and dimension ratio of the respective constituent features are not always consistent among drawings.

### First Embodiment

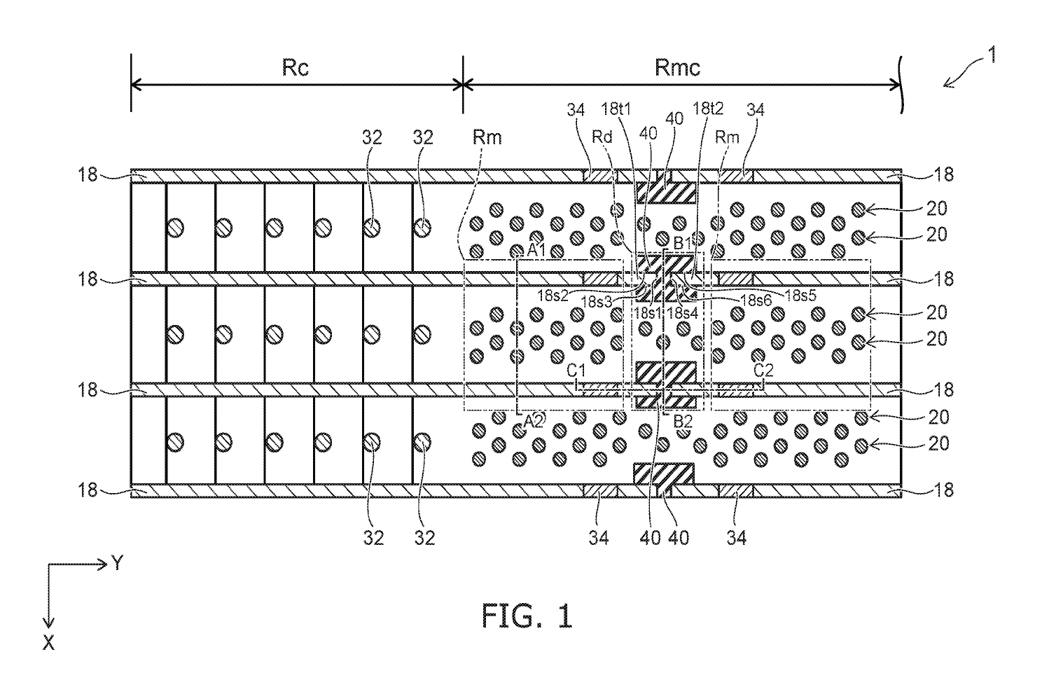

FIG. 1 is a plan view showing a semiconductor memory device according to a first embodiment.

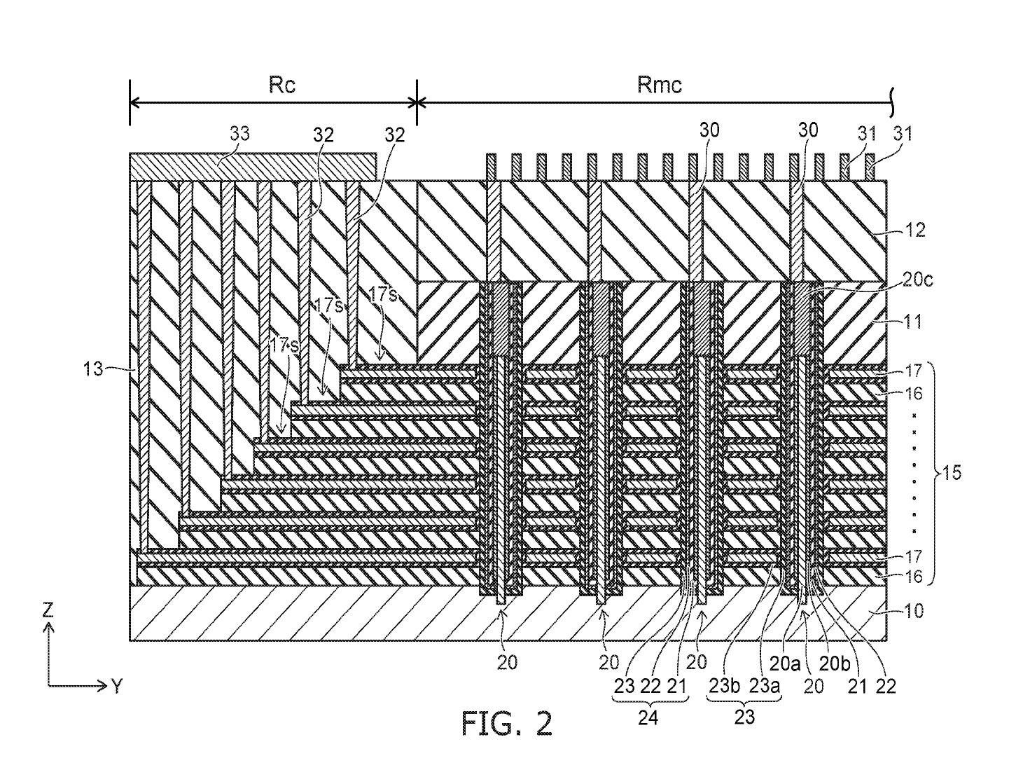

FIG. 2 is a sectional view showing the semiconductor memory device according to the first embodiment.

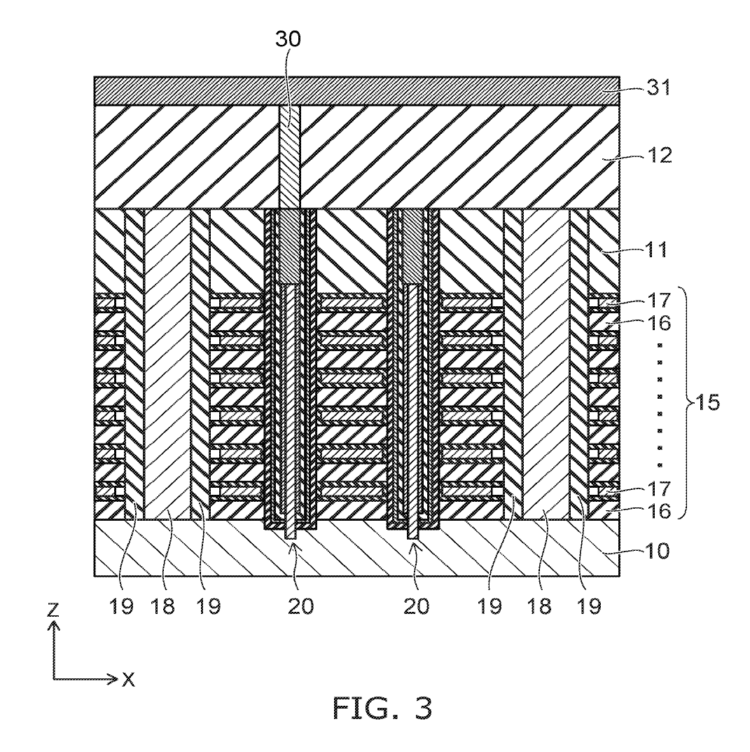

FIG. 3 to FIG. 5 are sectional views showing portions of the semiconductor memory device according to the first embodiment.

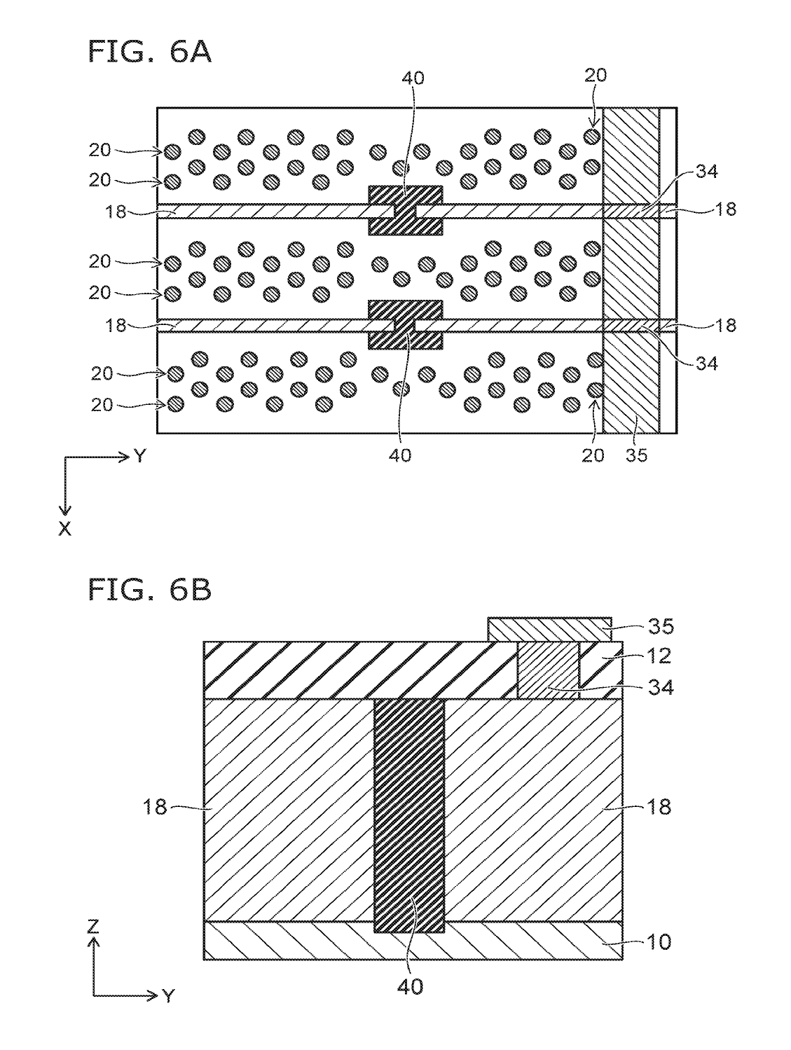

FIG. 6A and FIG. 6B are a plan view and a sectional view showing portions of another semiconductor memory device according to the first embodiment.

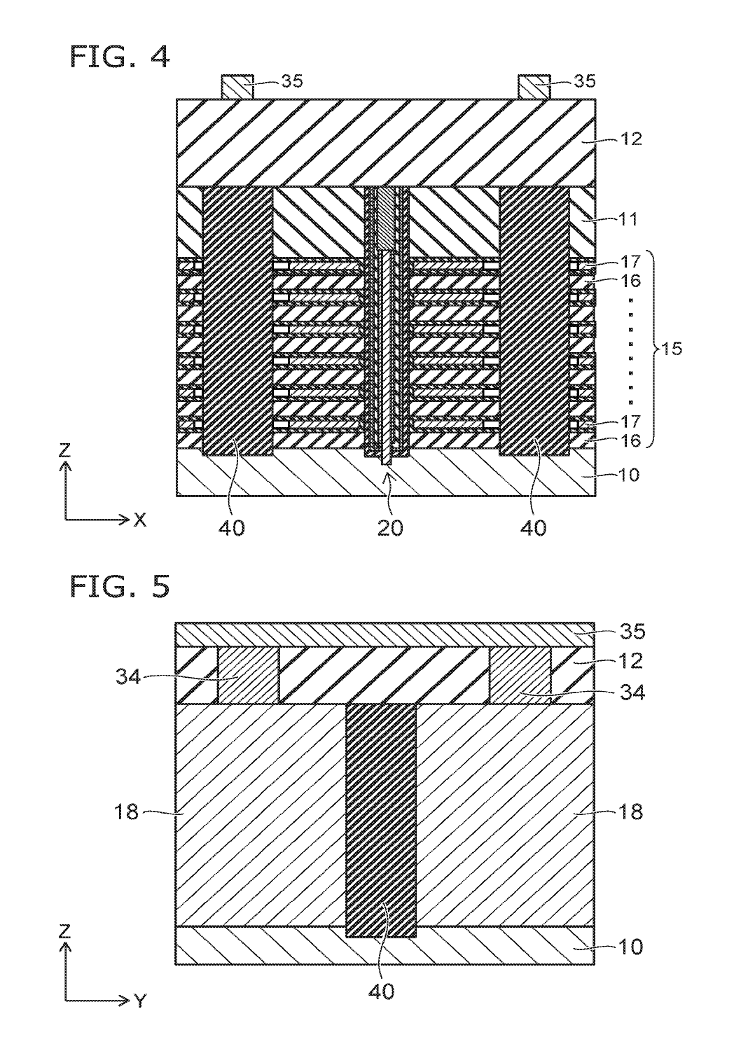

FIG. 1 shows the plan view of the semiconductor memory device 1. FIG. 2 shows a Y-Z sectional view of the semiconductor memory device 1. FIG. 3, FIG. 4, and FIG. 5 show sectional views along the line A1-A2, the line B1-B2, and the line C1-C2, respectively, of FIG. 1. FIG. 6A shows an enlarged view of a portion of FIG. 1. The cross-section of FIG. 6B corresponds to the cross-section of FIG. 5.

In the semiconductor memory device 1 according to the embodiment, a substrate 10 such as a silicon substrate is provided. Hereinafter, in the specification, an XYZ orthogonal coordinate system is employed for convenience of description. Two directions parallel to an upper surface of the substrate 10 and orthogonal to each other are defined as an “X-direction” and a “Y-direction”, and a direction vertical to the upper surface of the substrate 10 is defined as a “Z-direction”.

As shown in FIG. 1 and FIG. 2, in the semiconductor memory device 1, a memory cell area Rmc and a contact area Rc are provided. The memory cell area Rmc and the contact area Rc are arranged along the Y-direction.

Hereinafter, the memory cell area Rmc will be described.

In the memory cell area Rmc, stacked bodies 15 and silicon pillars 20 (semiconductor pillars) are provided. In the stacked body 15, a plurality of insulating films 16 and a plurality of electrode films 17 are alternately stacked one by one in the Z-direction. The numbers of the stacked layers of the insulating film 16 and the electrode film 17 may be arbitrary numbers. An inter-layer insulating film 11 is provided on the stacked body 15. The insulating film 16 is formed of, for example, silicon oxide (SiO₂). In the electrode film 17, a main body portion made of, for example, tungsten (W) or molybdenum (Mo), and a barrier metal layer made of, for example, titanium nitride and covering a surface of the main body portion are provided.

The silicon pillar 20 extends in the Z-direction. The silicon pillar 20 pierces the inter-layer insulating film 11 and the stacked body 15, and a lower end of the silicon pillar 20 is in contact with the substrate 10. As shown in FIG. 1, the silicon pillars 20 are disposed in, for example, a staggered manner. The inter-layer insulating film 11 is formed of, for example, silicon oxide.

In each of the silicon pillars 20, a circular cylindrical core portion 20a located in the stacked body 15 and constituting the central portion of the silicon pillar 20, a circular tubular cover layer 20b provided around the core portion 20a, and a plug portion 20c provided on the core portion 20a and the cover layer 20b and located in the inter-layer insulating film 11 are provided. The silicon pillar 20 is formed of polysilicon as a whole. The shape of the core portion 20a may be a circular tubular shape, and an insulating member may be provided in the interior thereof.

A tunnel insulating film 21 is provided around the silicon pillar 20, that is, on a side surface thereof. The tunnel insulating film 21 is, for example, a silicon oxide film of a single layer, or an ONO film in which a silicon oxide layer, a silicon nitride layer, and a silicon oxide layer are stacked. A charge storage film 22 is provided around the tunnel insulating film 21. The charge storage film 22 is a film for storing electrical charges, is formed of, for example, a material having an electron trapping site, and is formed of, for example, silicon nitride (Si₃N₄).

A silicon oxide layer 23a made of silicon oxide is provided around the charge storage film 22. An aluminum oxide layer 23b made of aluminum oxide (Al₂O₃) is provided between the silicon oxide layer 23a and the electrode film 17 and between the insulating film 16 and the electrode film 17. A block insulating film 23 is configured of the silicon oxide layer 23a and the aluminum oxide layer 23b. A memory film 24 capable of storing electrical charges is configured of the tunnel insulating film 21, the charge storage film 22, and the block insulating film 23. Accordingly, the memory film 24 is disposed between the silicon pillar 20 and the electrode film 17.

A plug 30 extending in the Z-direction and piercing an insulating film 12 is provided in an area directly on the silicon pillar 20. The plug 30 is formed of, for example, a conductive material such as tungsten. The insulating film 12 is formed of, for example, silicon oxide. Bit lines 31 extending in the X-direction are provided on the insulating film 12. Each of the bit lines 31 is connected via one plug 30 to one silicon pillar 20 for each of the stacked bodies 15.

As shown in FIG. 3, a plurality of interconnect portions 18 is provided on the substrate 10. The plurality of interconnect portions 18 is arranged spaced from each other along the X-direction and extends in the Y-direction. Moreover, the plurality of interconnect portions 18 is arranged spaced from each other along the Y-direction. A lower end of the interconnect portion 18 is in contact with the upper surface of the substrate 10. For example, the interconnect portion 18 is provided such that the width of an upper end in the X-direction and the width of the lower end in the X-direction are the same as each other. The interconnect portion 18 may be provided such that the width in the X-direction is smallest at the lower end, increases as it goes upward, and is largest at the upper end.

The stacked body 15 and the inter-layer insulating film are provided from bottom to top between every two interconnect portions 18 adjacent to each other in the X-direction. The stacked body 15 and the inter-layer insulating film 11 are defined by the interconnect portions 18 and extend in the Y-direction. Accordingly, the insulating film 16 and the electrode film 17 also extend in the Y-direction. The interconnect portion 18 has conductivity and is formed of, for example, a metal material made of tungsten or molybdenum.

An insulating side wall 19 is provided between a structure body composed of the stacked body 15 and the inter-layer insulating film 11 and the interconnect portion 18. The electrode film 17 is insulated from the interconnect portion 18 by the side wall 19. The side wall 19 also extends in the Y-direciton. The side wall 19 is formed of, for example, silicon oxide.

The memory cell area Rmc includes memory areas Rm and a dividing area Rd as shown in FIG. 1. The memory area Rm and the dividing area Rd are alternately provided along, for example, the Y-direction. In the memory area Rm, a memory cell including the memory film 24 is formed at each crossing portion between the silicon pillar 20 connected to the bit line 31 and the electrode films 17. That is, data can be stored in the memory cell in the memory area Rm. Moreover, in the memory area Rm, a contact 34 for electrically connecting to a source line 35 located in an upper layer is provided on each of the interconnect portions 18. Each of the interconnect portions 18 electrically connects with a control circuit (not shown) via the source line 35.

In the dividing area Rd, the silicon pillar 20 is not connected to the bit line 31, and the memory cell is not formed. For example, the silicon pillar 20 and the memory film 24 in the dividing area Rd are dummy portions and do not function as memory operation.

In the dividing area Rd, the interconnect portion 18 is divided. Moreover, in the dividing area Rd, columnar members 40 are provided. The columnar member 40 will be described in detail later.

Hereinafter, the contact area Rc will be described.

In the contact area Rc, the shape of an end portion of the stacked body 15 is a stepped shape, and a step 17s is formed for each of the electrode films 17. An insulating film 13 also covers the stepped-shaped end portion of the stacked body 15, and an upper surface of the insulating film 13 is flat. The insulating film 13 is formed of, for example, silicon oxide.

A contact 32 is provided on each of the steps 17s of each of the stacked bodies 15. Each of the contacts 32 extends in the Z-direction and pierces the insulating film 13. A lower end of the contact 32 is connected to the electrode film 17. Although, in the embodiment, one contact 32 is connected to each of the electrode films 17, a plurality of contacts 32 may be connected to each of the electrode films 17.

A plurality of upper-layer word lines 33 extending in the Y-direction is provided on the insulating film 13. An upper end of the contact 32 is connected to the upper-layer word line 33. For this reason, each of the electrode films 17 is connected to one upper-layer word line 33 via the contact 32.

In FIG. 2, for convenience of showing the drawing, a plurality of contacts 32 is drawn in the same Y-Z cross-section; actually, however, a plurality of contacts 32 connected to different electrode films 17 is disposed at positions different from each other in the X-direction. For this reason, one upper-layer word line 33 shown in FIG. 2 is connected to only one electrode film 17 via the contact 32.

In the memory cell area Rmc, the silicon pillar 20 is connected between the substrate 10 and the bit line 31. Moreover, in each of the electrode films 17, a plurality of blocks is disposed in an X-Y plane and forms a portion of an interconnect pattern. Moreover, each of the blocks corresponds to a portion between the interconnect portions 18 adjacent to each other and forms a word line as a control gate.

For example, in each of the blocks, four rows of the silicon pillars 20, each row of which is composed of a plurality of silicon pillars 20 arranged in a predetermined direction, are disposed. Each of the bit lines 31 extends in the X-direction over the plurality of blocks and is connected to one silicon pillar 20 for each of the blocks. The number of rows of the silicon pillar 20 may be an arbitrary number. Moreover, the number of the silicon pillars 20 or the number of rows of the silicon pillar 20 disposed in the memory area Rm, and the number of the silicon pillars 20 or the number of rows of the silicon pillar 20 disposed in the dividing area Rd may be arbitrary numbers. For example, in the example shown in FIG. 1, the number of rows of the silicon pillar 20 arranged in the memory area Rm is four, and the number of rows of the silicon pillar 20 arranged in the dividing area Rd is two. Moreover, the number of the silicon pillars 20 disposed in the dividing area Rd is less than the number of the silicon pillars 20 disposed in the memory area Rm.

In the memory cell area Rmc (the memory area Rm), a large number of memory cells are arranged in a three-dimensional matrix along the X-direction, the Y-direction, and the Z-direction, and data can be stored in each of the memory cells. On the other hand, in the contact area Rc, each of the electrode films 17 is led out of the memory cell area Rmc and connected to a peripheral circuit (not shown) via the contact 32 and the upper-layer word line 33.

Hereinafter, the columnar member 40 will be described.

As shown in FIG. 4, a plurality of the columnar members 40 is provided in the dividing area Rd and pierces the inter-layer insulating film 11 and the stacked body 15, and a lower end of the columnar member 40 is in contact with the substrate 10. For example, a portion of the columnar member 40 is buried in the substrate 10. The stacked body 15 and the inter-layer insulating film 11 are provided from bottom to top between two columnar members 40 adjacent to each other in the X-direction. The columnar member 40 is, for example, an insulating member and contains silicon oxide (SiO₂). The insulating film 12 is provided on the columnar member 40.

At least a portion of the columnar member 40 is located between two interconnect portions 18 adjacent to each other in the Y-direction. In the example shown in FIG. 1 and FIG. 5, the columnar member 40 is located between the two interconnect portions 18 so as to cover an end portion 18t1 of one of the interconnect portions 18 and an end portion 18t2 of the other interconnect portion 18. The end portion 18t1 and the end portion 18t2 are portions opposed in the Y-direction and disposed in the columnar member 40. For example, the shape of the end portion 18t1 and the end portion 18t2 is a rectangular parallelepiped. The end portion 18t1 and the end portion 18t2 constitute a dividing portion of the interconnect portion 18.

In the specification, the term “opposed” includes, in addition to the case where objects are in direct contact with each other, the case where another layer or film is inserted between the objects.

The columnar member 40 covers a side surface 18s1 of the end portion 18t1 and a side surface 18s4 of the end portion 18t2. The side surface 18s1 is a surface located between a side surface 18s2 and a side surface 18s3, and the side surface 18s4 is a surface located between a side surface 18s5 and a side surface 18s6.

The columnar member 40 covers the side surfaces 18s2, 18s3 of the end portion 18t1 and the side surfaces 18s5, 18s6 of the end portion 18t2. The side surface 18s2 is a surface opposed to the side surface 18s3, and the side surface 18s5 is a surface opposed to the side surface 18s6. Due to this, the columnar member 40 is disposed so as to have a predetermined width in a +X-direction and a −X-direction with the interconnect portion 18 being as a reference. Since the columnar member 40 has the width in the +X-direction and the −X-direction, a width between the two columnar members 40 adjacent to each other in the X-direction is smaller than a width between the interconnect portions 18 adjacent to each other in the X-direction.

As described above, the contact 34 is provided, on each of the interconnect portions 18, in the insulating film 12. Each of the interconnect portions 18 is electrically connected via the contact 34 to the source line 35 extending in the Y-direction. The columnar member 40 overlaps a portion of the source line 35 in the Z-direction.

The connection between each of the interconnect portions 18 and the source line 35 is not limited to the example described above, and the contact 34 may be provided on each of the interconnect portions 18 so as to be electrically connected to a source line 35 extending in the X-direction. For example, as shown in FIG. 6A and FIG. 6B, the contact 34 is provided on each of the interconnect portions 18 disposed along the X-direction. Each of the interconnect portions 18 is electrically connected via the contact 34 to the source line 35 extending in the X-direction. In this case, the columnar member 40 does not overlap the source line 35 in the Z-direction.

Hereinafter, a method for manufacturing the semiconductor memory device according to the embodiment will be described.

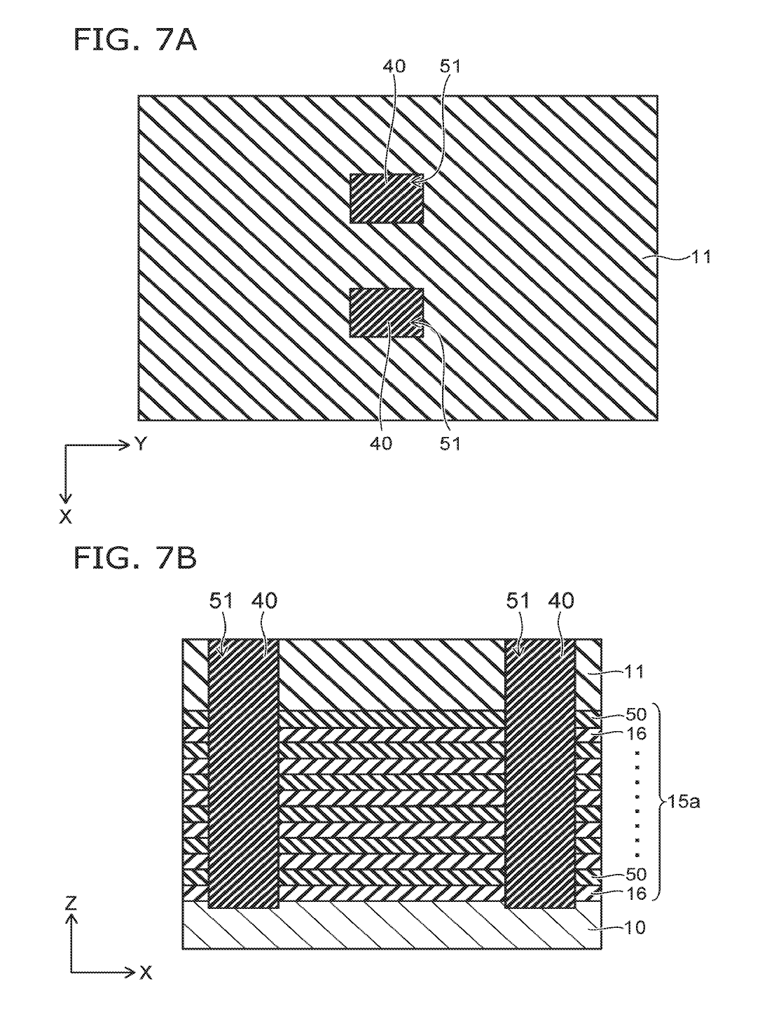

FIG. 7A and FIG. 7B to FIG. 10A and FIG. 10B are diagrams showing the method for manufacturing the semiconductor memory device according to the first embodiment.

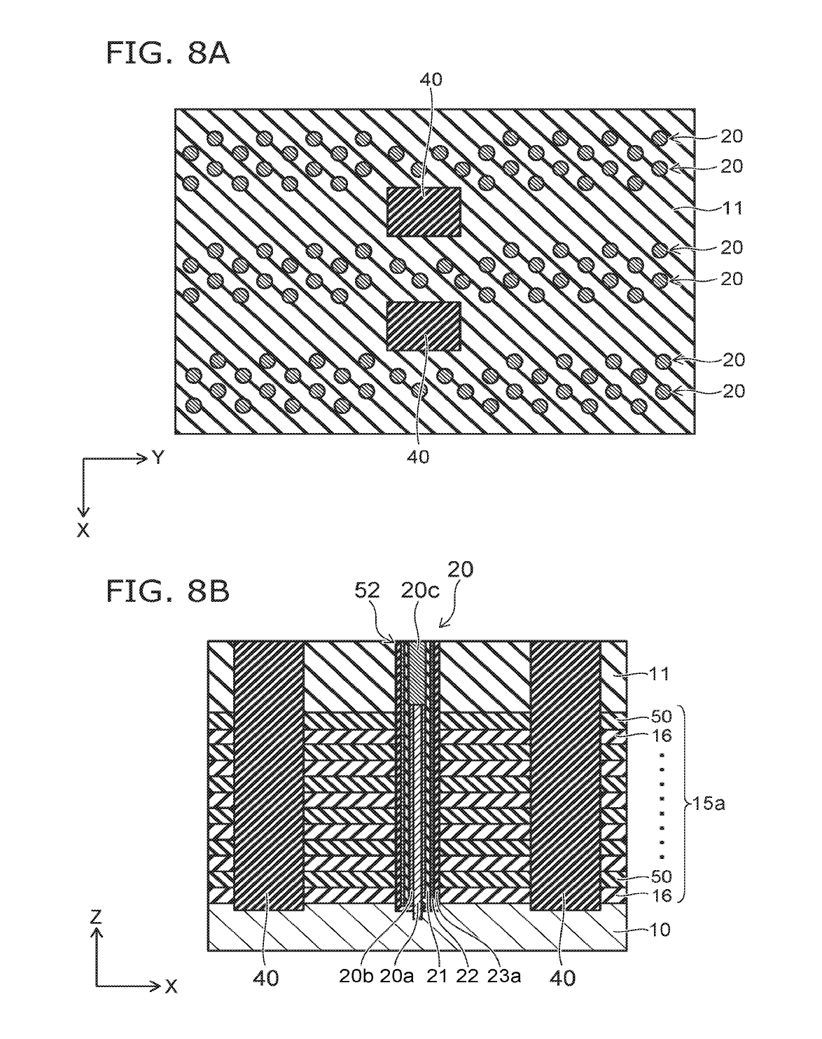

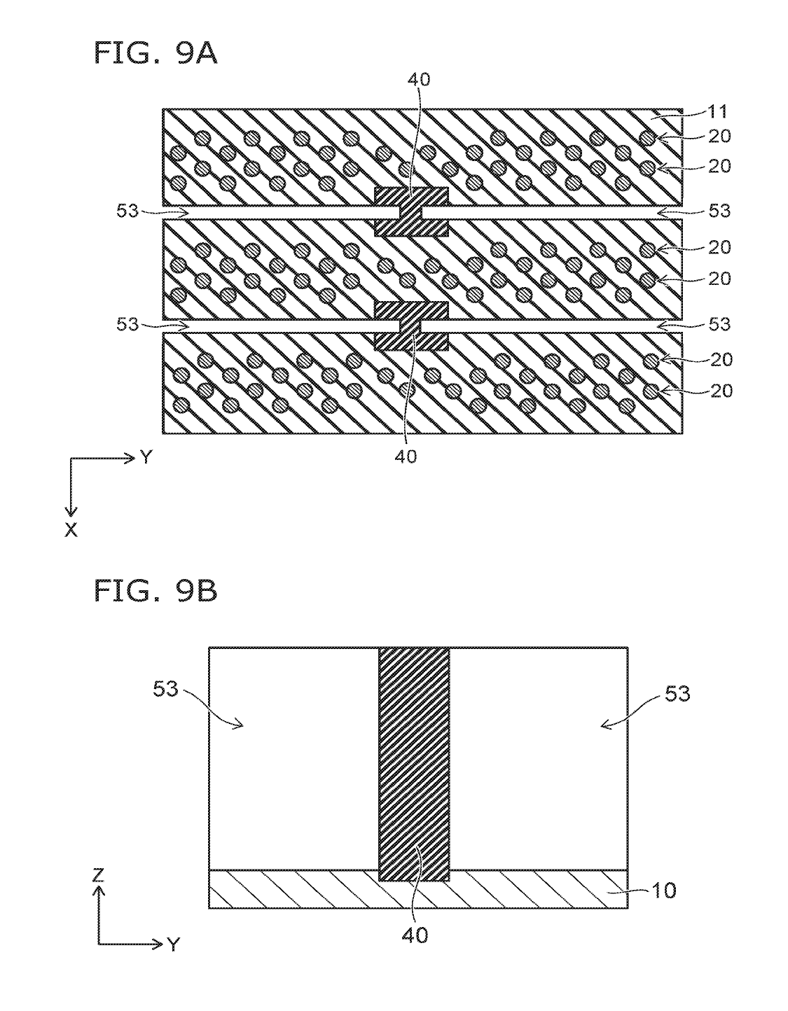

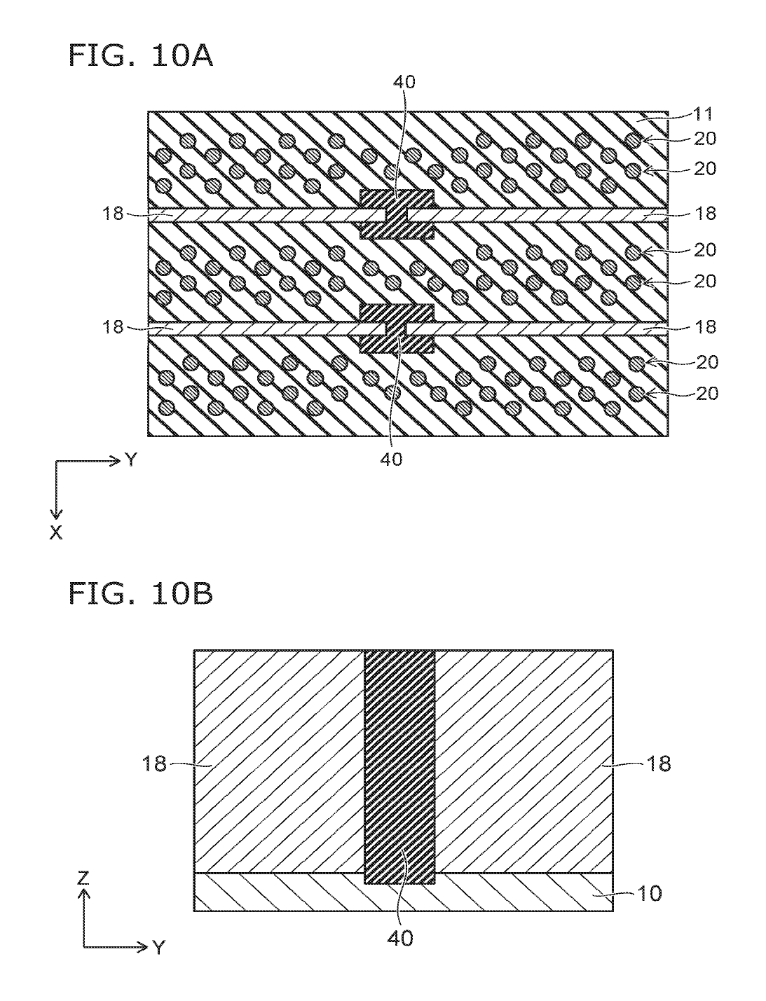

FIG. 7A to FIG. 10A and FIG. 7B to FIG. 10B show plan views and sectional views, respectively, showing the method for manufacturing the semiconductor memory device. FIG. 7A to FIG. 10A show enlarged views of a portion of FIG. 1, and the planes of FIG. 7A to FIG. 10A correspond to the plane of FIG. 6A. The cross-sections of FIG. 7B and FIG. 8B correspond to the cross-section of FIG. 4. The cross-sections of FIG. 9B and FIG. 10B correspond to the cross-section of FIG. 5. FIG. 7A and FIG. 7B to FIG. 10A and FIG. 10B show portions below the insulating film 12.

First, on the substrate 10 as a portion of a wafer, the insulating films 16 and sacrifice films 50 are alternately stacked along the Z-direction by, for example, a CVD (Chemical Vapor Deposition) method to form a stacked body 15a. The insulating film 16 is formed of, for example, silicon oxide. The sacrifice film 50 is formed of a material with which etching selectivity is obtained between the insulating film 16 and the sacrifice film 50, and is formed of, for example, silicon nitride. Subsequently, the inter-layer insulating film 11 is formed on the stacked body 15a.

Next, as shown in FIG. 7A and FIG. 7B, a plurality of holes 51 (through-holes) is formed in the inter-layer insulating film 11 and the stacked body 15a by, for example, RIE (Reactive Ion Etching). The hole 51 extends in the Z-direction to pierce the inter-layer insulating film 11 and the stacked body 15a, and reaches the substrate 10. The plurality of holes 51 is formed so as to have a predetermined interval in the X-direction. Moreover, the shape of the hole 51 is, for example, a rectangular parallelepiped. The shape of the hole 51 may be a circular cylinder or an elliptical cylinder.

Subsequently, silicon oxide is deposited in the hole 51 by, for example, a CVD method to form the columnar member 40. A portion of the columnar member 40 is buried in the substrate 10.

Next, as shown in FIG. 8A and FIG. 8B, a plurality of memory holes 52 (through-holes) is formed in the inter-layer insulating film 11 and the stacked body 15a by, for example, a photolithography method and RIE. The memory hole 52 extends in the Z-direction to pierce the inter-layer insulating film 11 and the stacked body 15a, and reaches the substrate 10. For example, the plurality of memory holes 52 is formed such that the number of rows of the memory hole 52 arranged in the vicinity of the columnar member 40 is reduced. The shape of the memory hole 52 is, for example, a circular cylinder. The shape of the memory hole 52 may be an elliptical cylinder or a rectangular parallelepiped. Moreover, as viewed in the Z-direction, the memory holes 52 are disposed in, for example, a staggered manner.

Subsequently, by, for example, a CVD method, silicon oxide is deposited on an inner surface of the memory hole 52 to form the silicon oxide layer 23a, silicon nitride is deposited to form the charge storage film 22, silicon oxide is deposited to form the tunnel insulating film 21, and silicon is deposited to form the cover layer 20b. Then, by applying RIE, the cover layer 20b, the tunnel insulating film 21, the charge storage film 22, and the silicon oxide layer 23a are removed from a bottom surface of the memory hole 52 to expose the substrate 10. Thereafter, silicon is deposited to form the core portion 20a. The core portion 20a reaches the substrate 10 and is in contact with the substrate 10. Then, etch-back is applied to remove upper portions of the cover layer 20b and the core portion 20a, and silicon into which an impurity is introduced is buried to form the plug portion 20c. Due to this, the silicon pillar 20 is formed in the memory hole 52.

Next, as shown in FIG. 9A and FIG. 9B, a plurality of slits 53 extending in the Y-direction is formed in the stacked body 15a by, for example, anisotropic etching such as RIE. The slits 53 are caused to pierce the stacked body 15a. Due to this, the stacked body 15a is divided by the slits 53 into a plurality of stacked bodies extending in the Y-direction. Moreover, a portion of the columnar member 40 is removed by the slit 53. A portion of the columnar member 40 is located between the slits 53 extending in the Y-direction. The columnar member 40 covers a portion of the slit 53.

Next, as shown in FIG. 10A and FIG. 10B, the sacrifice films 50 are removed by applying wet etching through the slits 53. The sacrifice films 50 are removed through the slits 53, so that cavities are formed. Thereafter, after the aluminum oxide layer 23b is formed through the slits 53, a conductive film such as tungsten or molybdenum is deposited to be buried in the cavities. Thereafter, the conductive film remaining in the slit 53 is removed by RIE and wet etching. Due to this, the electrode film 17 is formed in the cavity. The sacrifice film 50 is replaced with the electrode film 17, and the stacked body 15 is formed between the slits 53.

Subsequently, after silicon oxide is deposited on the entire surface to form an insulating film, the side wall 19 is formed by etching back this insulating film and leaving the insulating film on a side surface of the slit 53. Thereafter, a conductive film is formed by depositing tungsten or molybdenum to be thick. Due to this, the interconnect portion 18 is formed in the slit 53. Hence, the columnar member 40 is formed in the vicinity (the dividing area Rd) of the dividing place of the interconnect portion 18.

In this manner, the semiconductor memory device 1 according to the embodiment is manufactured.

Hereinafter, advantages of the embodiment will be described.

In the embodiment, the columnar member 40 is provided between the interconnect portions 18 extending in the stacked body 15. When the columnar member 40 is provided in this manner, the columnar member 40 can be used as a support body in the stacked body 15a when the sacrifice films 50 are removed through the slits 53 for forming the electrode films 17 and the interconnect portions 18. Due to this, it is possible to suppress the distortion of the stacked body 15 and suppress the defect of the semiconductor memory device 1 to improve yield.

In a semiconductor memory device having a three-dimensional structure, slits reaching a substrate are formed and a conductive film is formed in the slits, so that interconnect portions in contact with the substrate are formed. When the slits are formed, a stacked body is divided into a plurality of stacked bodies extending in the Y-direction. Moreover, sacrifice films are removed through the slits, so that a cavity is formed in the forming portions of the sacrifice films. Hence, in a process for forming an electrode film and the interconnect portion, spaces such as the slit and the cavity are formed in the stacked body.

On the other hand, the stacked body after the sacrifice films are removed has a structure in which a silicon pillar, a memory film, or the like pierces insulating films, and has an internal stress such as a compressive stress or a tensile stress based on the forming material of a structure body. At this time, if the columnar member 40 is not provided, a support body in the stacked body is insufficient due to the formation of the slit and the cavity, and therefore, the stacked body may be distorted by the internal stress.

Further, when the electrode film is formed of a metal material, a tensile stress is likely to occur in the Y-direction and a compressive stress is likely to occur in the X-direction. Because of the difference in the stress occurring in each of the directions of the electrode film, when the stacked body formed with the slit and the cavity is distorted by the internal stress, there is a risk that the stacked body after the formation of the electrode film will be further distorted.

The columnar member 40 of the embodiment is provided between the interconnect portions 18, and functions as a support body in the stacked body 15a when spaces for forming the electrode film 17 and the interconnect portion 18 are produced. Hence, the columnar member 40 suppresses the distortion of the stacked body 15 occurring due to the internal stress of the stacked body 15.

### Second Embodiment

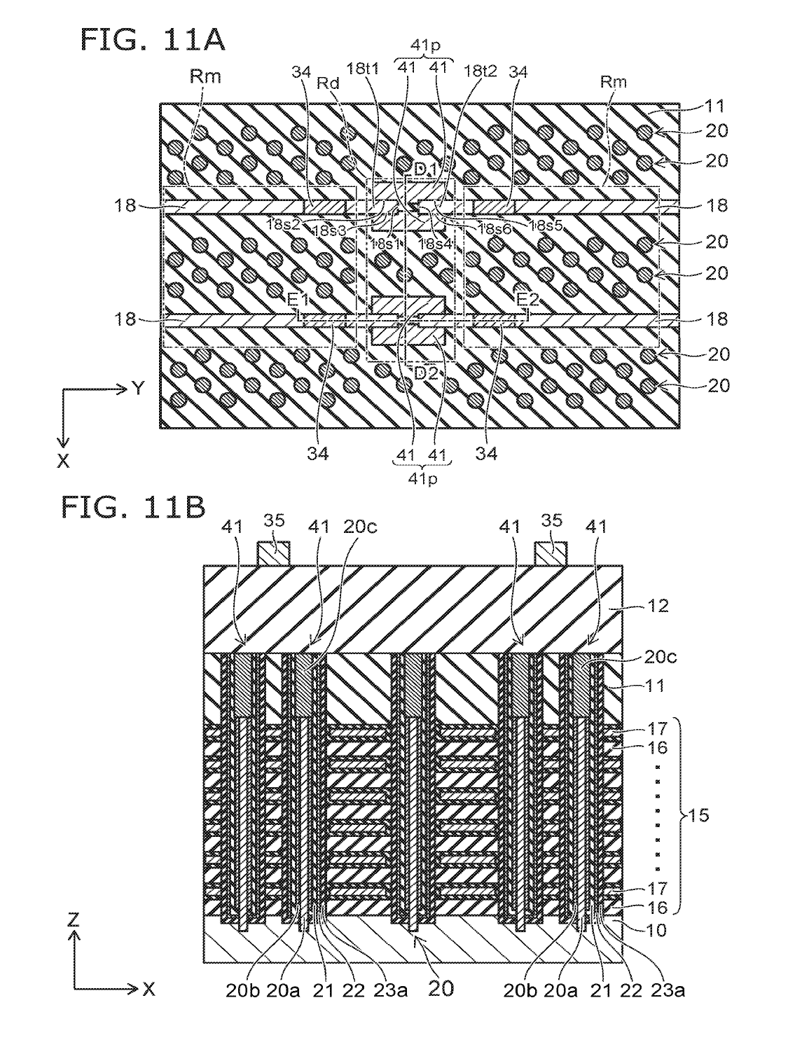

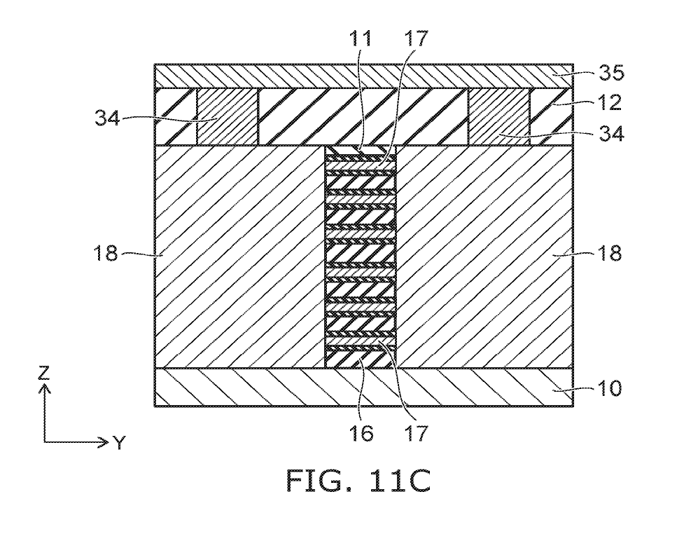

FIG. 11A is a plan view showing a portion of a semiconductor memory device according to a second embodiment.

FIG. 11B and FIG. 11C are sectional views showing portions of the semiconductor memory device according to the second embodiment.

FIG. 11A is the plan view of the portion of the semiconductor memory device 1, showing an enlarged view of FIG. 1. FIG. 11B and FIG. 11C show sectional views along the line D1-D2 and the line E1-E2 of FIG. 11A. The embodiment and the first embodiment are different in a columnar member 41. Configurations other than the columnar member 41 are the same as the first embodiment, and therefore, a detailed description of other configurations is omitted.

As shown in FIG. 11A to FIG. 11C, a plurality of the columnar members 41 is provided in the dividing area Rd and pierces the inter-layer insulating film 11 and the stacked body 15, and a lower end of the columnar member 41 is in contact with the substrate 10. The shape of the columnar member 41 is, for example, a rectangular parallelepiped. The columnar member 41 is formed of at least a portion of materials forming the silicon pillar 20 and the memory film 24. That is, the columnar member 41 is formed of at least a portion of materials filled in the memory hole 52. For example, as shown in FIG. 11B, the columnar member 41 includes the core portion 20a, the cover layer 20b, the plug portion 20c, the tunnel insulating film 21, the charge storage film 22, and the silicon oxide layer 23a.

The columnar members 41 are provided in sets each composed of two columnar members 41, at positions interposing an extended line of the interconnect portion 18 therebetween. Sets 41p each composed of the two columnar members 41 are provided spaced from each other along the X-direction, and the stacked body 15 and the inter-layer insulating film 11 are provided from bottom to top between two sets 41p adjacent to each other in the X-direction. Moreover, also between the two columnar members 41 in the set 41p, the stacked body 15 and the inter-layer insulating film 11 are provided from bottom to top.

In each of the columnar members 41 in the set 41p, a portion of the columnar member 41 is located between the two interconnect portions 18 adjacent to each other in the Y-direction. The two columnar members 41 in the set 41p are located between the two interconnect portions 18 so as to cover a portion of the end portion 18t1 and a portion of the end portion 18t2. The two columnar members 41 in the set 41p cover a portion of the side surface 18s1 of the end portion 18t1 and a portion of the side surface 18s4 of the end portion 18t2. Moreover, the two columnar members 41 in the set 41p cover the side surfaces 18s2, 18s3 of the end portion 18t1 and the side surfaces 18s5, 18s6 of the end portion 18t2.

Hereinafter, a method for manufacturing the semiconductor memory device according to the embodiment will be described.

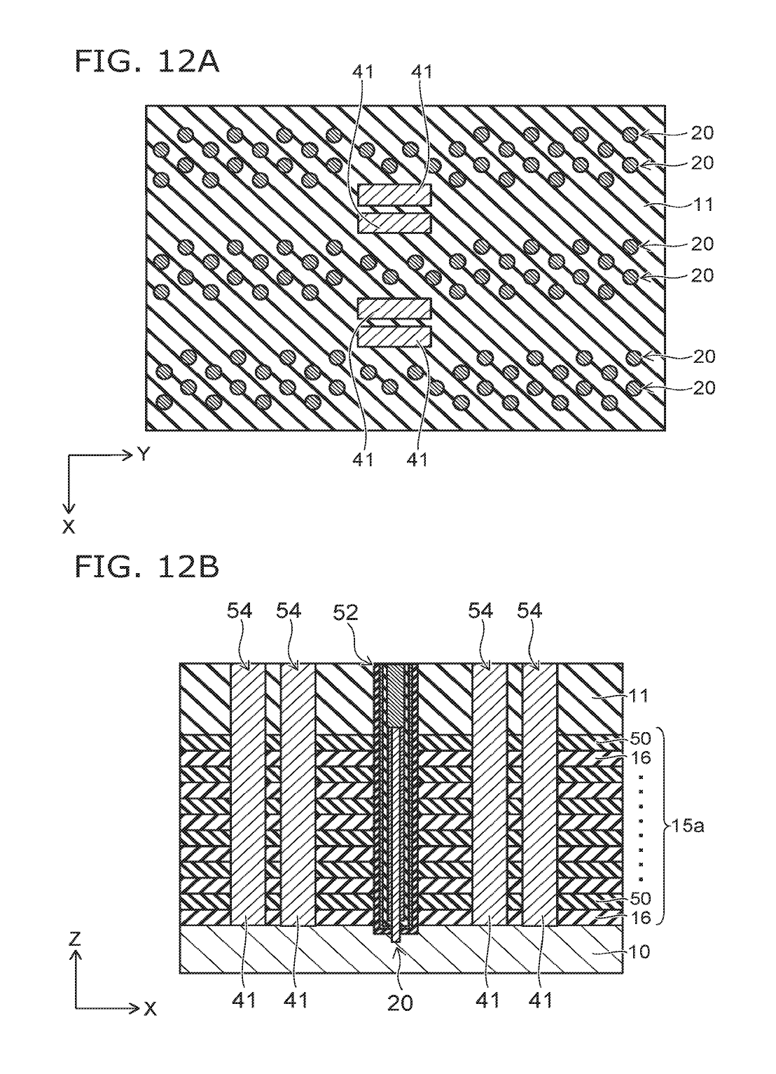

FIG. 12A and FIG. 12B to FIG. 14A and FIG. 14B are diagrams showing the method for manufacturing the semiconductor memory device according to the second embodiment.

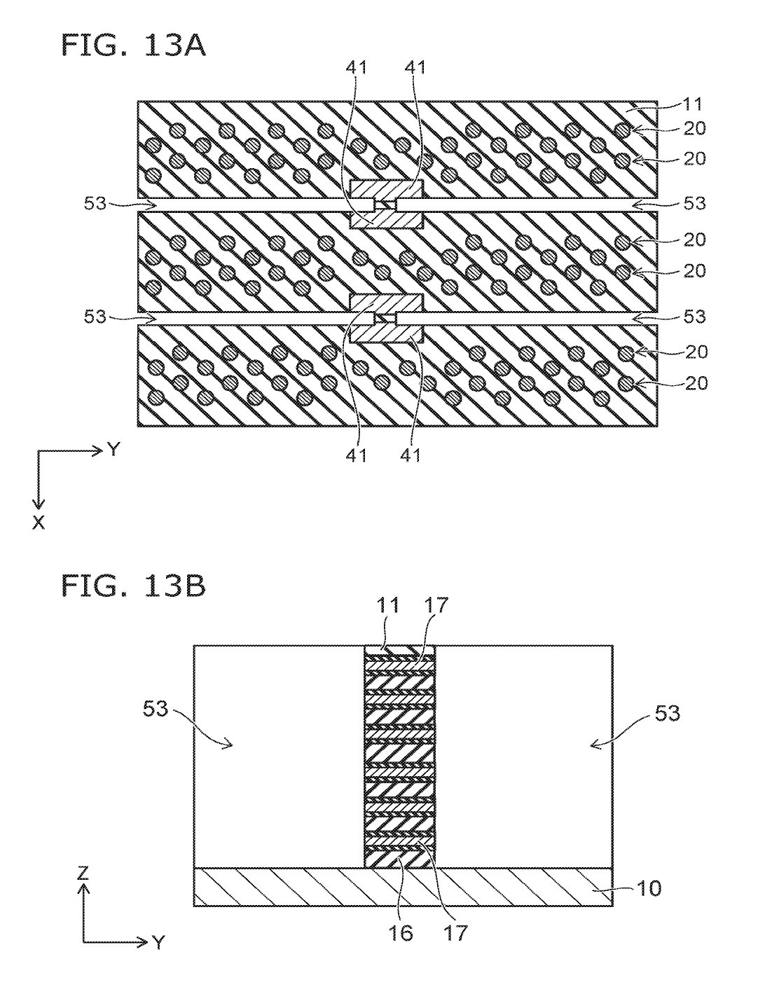

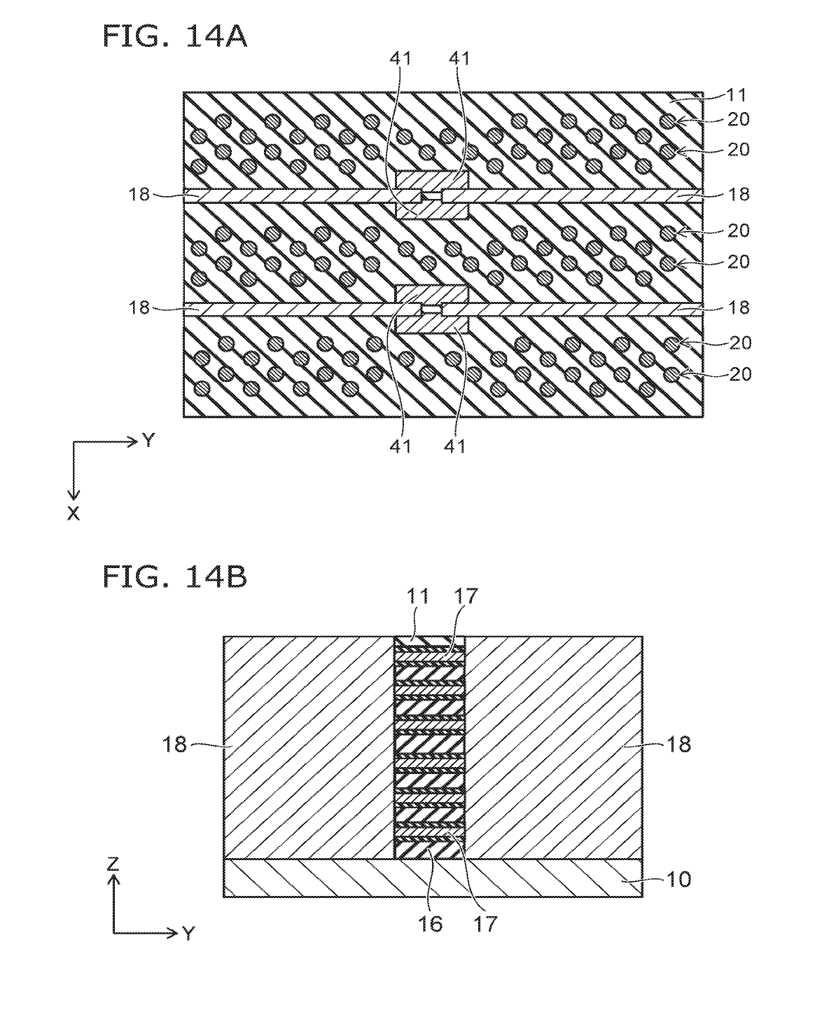

FIG. 12A to FIG. 14A and FIG. 12B to FIG. 14B show plan views and sectional views, respectively, showing the method for manufacturing the semiconductor memory device. The planes of FIG. 12A to FIG. 14A correspond to the plane of FIG. 11A. The cross-section of FIG. 12B corresponds to the cross-section of FIG. 11B. The cross-sections of FIG. 13B and FIG. 14B correspond to the cross-section of FIG. 11C. FIG. 12A and FIG. 12B to FIG. 14A and FIG. 14B show portions below the insulating film 12.

First, the insulating films 16 and the sacrifice films 50 are alternately stacked along the Z-direction on the substrate 10 to form the stacked body 15a. Subsequently, the inter-layer insulating film 11 is formed on the stacked body 15a.

Next, as shown in FIG. 12A and FIG. 12B, the plurality of memory holes 52 and a plurality of holes 54 are formed in the inter-layer insulating film 11 and the stacked body 15a by, for example, a photolithography method and RIE. The memory hole 52 and the hole 54 extend in the Z-direction to pierce the inter-layer insulating film 11 and the stacked body 15a, and reach the substrate 10. The plurality of holes 54 is formed so as to have predetermined intervals in the X-direction. The holes 54 are formed in sets each composed of two holes 54. Moreover, the shape of the hole 54 is, for example, a rectangular parallelepiped. The shape of the hole 54 may be a circular cylinder or an elliptical cylinder.

Subsequently, the silicon pillar 20 and the memory film 24 are formed in the memory hole 52 by, for example, a CVD method. Moreover, at least a portion of the materials forming the silicon pillar 20 and the memory film 24 is also filled in the hole 54. Due to this, the columnar member 41 is formed.

Next, as shown in FIG. 13A and FIG. 13B, the plurality of slits 53 extending in the Y-direction is formed in the stacked body 15a by, for example, anisotropic etching such as RIE. The slits 53 are caused to pierce the stacked body 15a. Due to this, the stacked body 15a is divided by the slits 53 into a plurality of stacked bodies extending in the Y-direction. Moreover, a portion of the columnar member 41 is removed by the slit 53. A portion of each of the columnar members 41 is located between the slits 53 extending in the Y-direction. Each of the columnar members 41 covers a portion of the slit 53.

Subsequently, the sacrifice films 50 are removed by applying wet etching through the slits 53. The sacrifice films 50 are removed through the slits 53, so that cavities are formed. Thereafter, after the aluminum oxide layer 23b is formed through the slits 53, a conductive film is deposited to be buried in the cavities. Due to this, the electrode films 17 are formed. The sacrifice film 50 is replaced with the electrode film 17, and the stacked body 15 is formed between the slits 53.

Next, as shown in FIG. 14A and FIG. 14B, after the side wall 19 is formed on a side surface of the slit 53, a conductive film is formed. Due to this, the interconnect portion 18 is formed in the slit 53. Hence, the columnar member 41 is formed in the vicinity (the dividing area Rd) of the dividing place of the interconnect portion 18.

In this manner, the semiconductor memory device 1 according to the embodiment is manufactured.

Hereinafter, an advantage of the embodiment will be described.

In the embodiment, the columnar member 41 including at least a portion of the materials filled in the memory hole 52 is provided between the interconnect portions 18 extending in the stacked body 15. When the columnar member 41 is provided in this manner, the columnar member 41 can be formed in the hole 54 when the silicon pillar 20 and the memory film 24 are formed in the memory hole 52. Due to this, a manufacturing process of the semiconductor memory device 1 can be shortened.

Advantages other than that described above in the embodiment are similar to the first embodiment described above.

### Third Embodiment

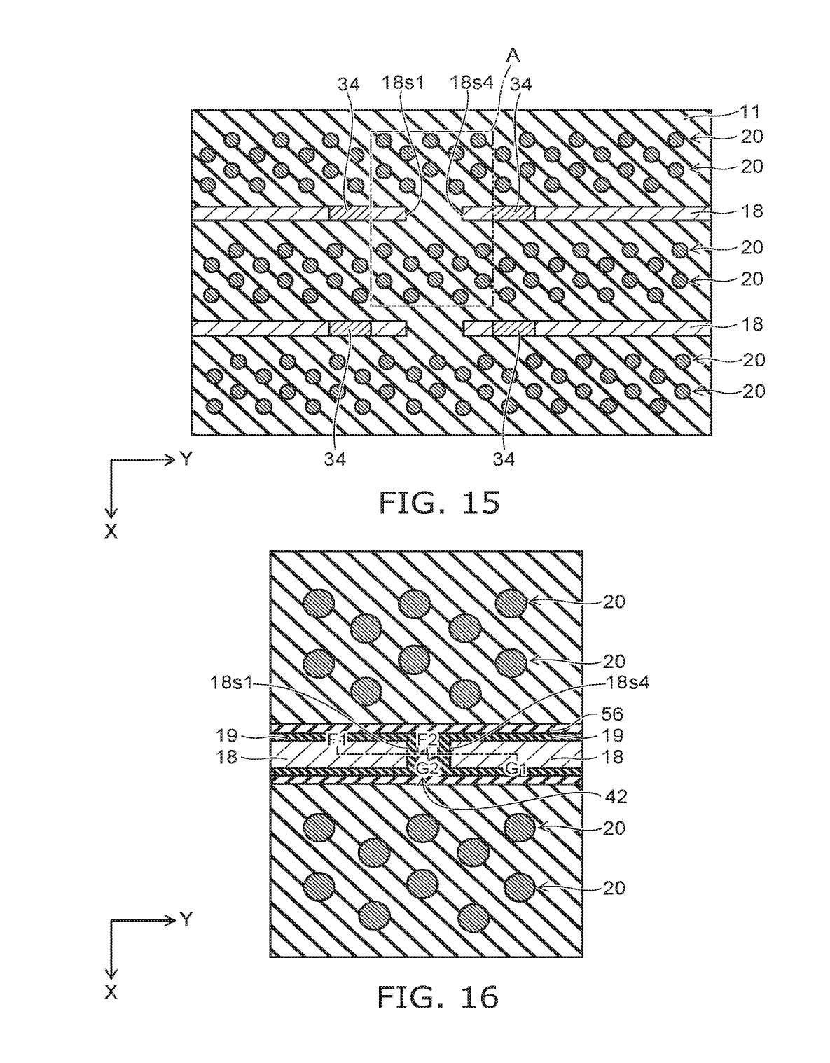

FIG. 15 is a plan view showing a portion of a semiconductor memory device according to a third embodiment.

FIG. 16 is a plan view showing a portion of the semiconductor memory device according to the third embodiment.

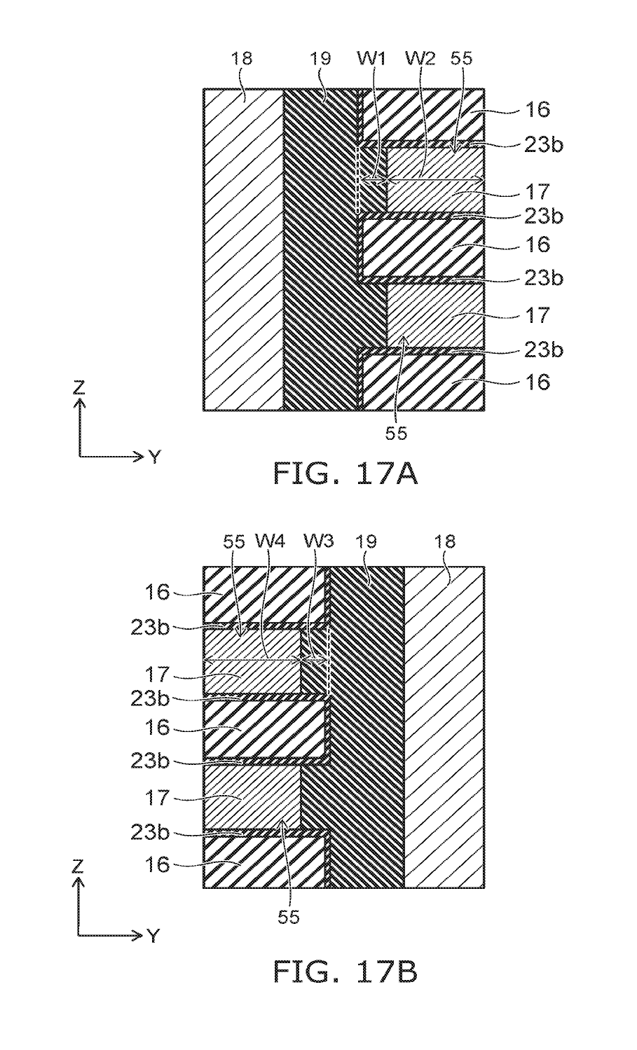

FIG. 17A and FIG. 17B are sectional views showing portions of the semiconductor memory device according to the third embodiment.

FIG. 15 is the plan view of the portion of the semiconductor memory device 1, showing an enlarged view of FIG. 1. FIG. 16 shows an enlarged view of an area A of FIG. 15. FIG. 17A and FIG. 17B show enlarged sectional views along the line F1-F2 and the line G1-G2 of FIG. 16.

The embodiment and the first embodiment are different in a columnar member 42. Configurations other than the columnar member 42 are the same as the first embodiment, and therefore, a detailed description of other configurations is omitted.

As shown in FIG. 15 and FIG. 16, the side walls 19 cover the side surfaces 18s1, 18s4 of the interconnect portions 18. Since the side surfaces 18s1, 18s4 of the interconnect portions 18 are covered by the side walls 19, the electrode films 17 stacked in the Z-direction between the interconnect portions 18 adjacent to each other in the Y-direction can be electrically insulated.

Hereinafter, a method for forming the columnar member 42 will be described.

As shown in FIG. 17A and FIG. 17B, the volume of the electrode film 17 formed in a cavity 55 is reduced between the interconnect portions 18 adjacent to each other in the Y-direction, so that the volume of the side wall 19 formed in the cavity 55 can be increased. For example, when the electrode film 17 is formed by depositing a conductive film and burying the conductive film in the cavity, the volume of the conductive film recessed in the cavity 55 by etching is controlled, and thus the volume of the side wall 19 formed in the cavity 55 can be increased. That is, a width W1, W3 of the side wall 19 in the cavity 55 increases, and a width W2, W4 of the electrode film 17 decreases.

The width W1, W3 of the side wall 19 in the cavity 55 increases, so that an insulating structure body 56 including the side wall 19 and the insulating film 16 is formed. For example, between the interconnect portions 18, the conductive film in the cavity 55 may be entirely removed to form the side wall 19. In this case, as shown in FIG. 16, the columnar member 42, which is insulating, is disposed due to the side wall 19 and the insulating film 16 between the interconnect portions 18. Moreover, an interval between the interconnect portions 18 is the same as the width of the conductive film recessed by etching. For example, in FIG. 17A and FIG. 17B, when the widths of the conductive films recessed by etching are the same as each other, the interval between the interconnect portions 18 is twice the width of the conductive film shown in FIG. 17A.

Hereinafter, advantages of the embodiment will be described.

As in the embodiment, the volume of the electrode film 17 in the cavity 55 is controlled between the interconnect portions 18, so that the volume of the side wall 19 in the cavity 55 can be increased. Due to this, after the electrode film 17 is formed by replacing the sacrifice film 50, the interconnect portions 18 can be electrically insulated.

Moreover, since a process for forming a hole and burying a deposit in the hole (for example, the process shown in FIG. 7A and FIG. 7B or FIG. 12A and FIG. 12B) does not need to be applied, the manufacturing process of the semiconductor memory device 1 can be shortened.

Further, when the electrode film 17 is formed in the cavity 55, the insulating film 16 is disposed between the slits 53; and when the interconnect portion 18 is formed in the slit 53, the insulating structure body 56 (for example, the columnar member 42) including the side wall 19 and the insulating film 16 is disposed between the slits 53. Due to this, the insulating film 16 and the side wall 19 function as a support body in the stacked body 15 and thus suppress the distortion of the stacked body 15 occurring due to the internal stress of the stacked body 15.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a stacked body provided on the substrate and including a plurality of electrode films stacked separately from each other;
a semiconductor pillar provided in the stacked body and extending in a stacking direction of the stacked body;
a charge storage film provided between the semiconductor pillar and the stacked body;
a plurality of interconnect portions provided in the stacked body, each spreading along the stacking direction and a first direction crossing the stacking direction, and disposed along the first direction and a second direction crossing the stacking direction and the first direction; and
at least one columnar member provided in the stacked body and extending in the stacking direction,
the plurality of interconnect portions including a first interconnect portion and a second interconnect portion adjacent to each other in the first direction,
the columnar member being located between a first end portion of the first interconnect portion and a second end portion of the second interconnect portion.

2. The device according to claim 1, wherein
the columnar member covers the first end portion and the second end portion.

3. The device according to claim 1, wherein
a shape of the first end portion is a rectangular parallelepiped,
a shape of the second end portion is a rectangular parallelepiped, and
the columnar member covers a side surface of the first end portion and a side surface of the second end portion.

4. The device according to claim 1, wherein the columnar member contains silicon oxide.

5. The device according to claim 1, wherein
the columnar member contains at least any material of a material of which the semiconductor pillar is formed and a material of which the charge storage film is formed.

6. The device according to claim 1, wherein
the columnar member covers the first end portion and the second end portion, and
a shape formed of the columnar member, the first end portion, and the second end portion is any of a rectangular parallelepiped, a circular cylinder, and an elliptical cylinder.

7. The device according to claim 1, wherein
the columnar member includes a first columnar member and a second columnar member,
a shape of the first end portion is a rectangular parallelepiped,
a shape of the second end portion is a rectangular parallelepiped,
the first end portion includes a first side surface, a second side surface, and a third side surface,
the second end portion includes a fourth side surface, a fifth side surface, and a sixth side surface,
the first columnar member covers a first portion of the first side surface, the second side surface, a second portion of the fourth side surface, and the fifth side surface, and
the second columnar member covers a third portion of the first side surface, the third side surface, a fourth portion of the fourth side surface, and the sixth side surface.

8. The device according to claim 7, wherein
the first columnar member and the second columnar member are disposed separately along the second direction.

9. The device according to claim 7, wherein
the first columnar member and the second columnar member contain at least any material of a material of which the semiconductor pillar is formed and a material of which the charge storage film is formed.

10. The device according to claim 1, further comprising:
a first contact portion provided on the first interconnect portion;
a second contact portion provided on the second interconnect portion; and
a first interconnect connected to the first contact portion and the second contact portion and extending in the first direction.

11. The device according to claim 10, wherein
the columnar member overlaps the first interconnect as viewed in the stacking direction.

12. The device according to claim 1, further comprising a second interconnect extending in the second direction, wherein
the plurality of interconnect portions includes a third interconnect portion and a fourth interconnect portion adjacent to each other in the first direction,
the third interconnect portion and the fourth interconnect portion are provided so as to be adjacent to the first interconnect portion and the second interconnect portion, respectively, in the second direction,
the columnar member includes a first columnar member located between end portions of the first interconnect portion and the second interconnect portion, and a second columnar member located between end portions of the third interconnect portion and the fourth interconnect portion, and
the second interconnect is not provided between the first columnar member and the second columnar member.

13. The device according to claim 12, further comprising:
a first contact portion provided on the first interconnect portion;
a third contact portion provided on the third interconnect portion; and
a third interconnect connected to the first contact portion and the third contact portion and extending in the second direction.

14. The device according to claim 13, wherein
the columnar member does not overlap the third interconnect as viewed in the stacking direction.

15. The device according to claim 12, wherein
a width between the first columnar member and the second columnar member is smaller than a width between the first interconnect portion and the third interconnect portion and a width between the second interconnect portion and the fourth interconnect portion.

16. A semiconductor memory device comprising:
a substrate;
a stacked body provided on the substrate and including a plurality of electrode films stacked separately from each other;
a semiconductor pillar provided in the stacked body and extending in a stacking direction of the stacked body;
a charge storage film provided between the semiconductor pillar and the stacked body;
a plurality of interconnect portions provided in the stacked body, each spreading along the stacking direction and a first direction crossing the stacking direction, and disposed along the first direction and a second direction crossing the stacking direction and the first direction; and
a plurality of columnar members provided in the stacked body and extending in the stacking direction,
the plurality of interconnect portions including a first interconnect portion and a second interconnect portion adjacent to each other in the first direction, and a third interconnect portion and a fourth interconnect portion adjacent to each other in the first direction,
the first interconnect portion and the second interconnect portion being provided so as to be adjacent to the third interconnect portion and the fourth interconnect portion, respectively, in the second direction,
the columnar member including a first columnar member located between a first end portion of the first interconnect portion and a second end portion of the second interconnect portion, and a second columnar member located between a third end portion of the third interconnect portion and a fourth end portion of the fourth interconnect portion.

17. The device according to claim 16, wherein
the first columnar member covers the first end portion and the second end portion, and
the second columnar member covers the third end portion and the fourth end portion.

18. The device according to claim 16, wherein
the first columnar member and the second columnar member contain silicon oxide.

19. The device according to claim 16, wherein
the columnar member includes a third columnar member located between the first end portion of the first interconnect portion and the second end portion of the second interconnect portion, and a fourth columnar member located between the third end portion of the third interconnect portion and the fourth end portion of the fourth interconnect portion,
the first columnar member and the third columnar member are disposed separately along the second direction,
the second columnar member and the fourth columnar member are disposed separately along the second direction,
the first columnar member and the third columnar member cover the first end portion and the second end portion, and
the second columnar member and the fourth columnar member cover the third end portion and the fourth end portion.

20. A method for manufacturing a semiconductor memory device, comprising:
alternately stacking, on a substrate, first insulating films and first films to form a stacked body;
forming, in the stacked body, a through-hole extending in a stacking direction of the stacked body;
forming, in the through-hole, a charge storage film and a semiconductor pillar;
forming, in the stacked body, a plurality of slits, each extending in the stacking direction and a first direction crossing the stacking direction, along the first direction and a second direction crossing the stacking direction and the first direction;
removing the first films through the plurality of slits;
forming, through the plurality of slits, a first conductive film in each of cavities resulting from the removal of the first films;
removing the first conductive films located between slits disposed in the first direction;
forming a second insulating film in each of the plurality of slits; and
forming a plurality of interconnect portions on the second insulating films in the plurality of slits.
